(19) United States
(12) Patent Application Publication
(10) Pub. No.: US 2003/0022466 A1
(43) Pub. Date: Jan. 30, 2003

(54) Structure and method for fabricating semiconductor structure and linearized monolithic power amplifier utilizing the formation of a compliant substrate for materials used to form the same

(75) Inventors: Nestor Javier Escalera, Gilbert, AZ (US); Rudy M. Emrick, Gilbert, AZ (US); Bruce Allen Bosco, Phoenix, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/911,446

(22) Filed: Jul. 25, 2001

(51) Int. Cl. H01L 21/20

(52) U.S. Cl. 438/478

(57) ABSTRACT

A semiconductor structure includes a monocrystalline silicon substrate, a buffer layer including an amorphous oxide material overlying the monocrystalline silicon substrate and a monocrystalline perovskite oxide material overlying the amorphous oxide material and a monocrystalline compound semiconductor material overlying the monocrystalline perovskite oxide material. The semiconductor structure further includes power amplifier and associated linearization circuit for the power amplifier.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer comprised of semiconductor material, compound semiconductor material, and/or other types of material such as metals and non-metals. More particularly, this invention relates to structure and methods for monolithic power amplifier circuits.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

For example, state of the art communication systems utilize highly linear power amplifier circuits for transmission of radio signals. Such power amplifiers are required, for example, in radios used in current code division multiple access (CDMA) communication systems and orthogonal frequency division multiplexing (OFDM)and other modulation formats such as quadrature phase shift keying (QPSK), offset QPSK (OQPSK). For achieving linearity, circuit design techniques such as power combining/backoff, multi-channelling, predistortion, adaptive predistortion, feedforward, adaptive feedforward and envelope feedback have been developed. These techniques all require additions to the basic power amplifier device.

Power amplifier devices are currently available as monolithic devices. However, the above-described techniques for achieving highly linear power in a radio all require the use of external components such as combiners/dividers, digital signal processors or other controllers, couplers, phase shifters, differential amplifiers, and delay lines. The use of these external components increases the complexity and cost of the power amplifier circuit and reduces the performance benefits that may be realized. Power amplifier devices are generally manufactured using compound semiconductor materials, such as Group III-V materials like gallium arsenide or indium phosphide. Size constraints and high cost of high-performance III-V semiconductor material prohibits the integration of some of these components into a single, monolithic integrated circuit. In some cases, even if cost and size were not constraints, total integration would not be possible due to the different material used to create the different components. This is particularly true for high-performance radio frequency (RF) power amplifier devices which are fabricated on III-V material such as gallium arsenide and associated digital signal processors which are typically fabricated on silicon.

Accordingly, a need exists for a semiconductor structure that provides a high quality monocrystalline film or layer over another monocrystalline material and for a process for making such a structure. Further, a need exists for method and apparatus which combine III-V and other compound semiconductor materials on a low-cost substrate such as silicon to integrate multiple functions for a highly linear power amplifier into a monolithic power amplifier system integrated circuit.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention; and

FIGS. 21-23 illustrate schematically, in cross-section, the formation of yet another embodiment of a device structure in accordance with the invention.

FIGS. 24, 25 illustrate schematically, in cross section, device structures that can be used in accordance with various embodiments of the invention.

FIGS. 26-30 include illustrations of cross-sectional views of a portion of an integrated circuit that includes a compound semiconductor portion, a bipolar portion, and an MOS portion in accordance with what is shown herein.

FIGS. 31-37 include illustrations of cross-sectional views of a portion of another integrated circuit that includes a semiconductor laser and a MOS transistor in accordance with what is shown herein.

FIG. 38 is a cross sectional view of a semiconductor structure;

FIG. 39 is a block diagram of an embodiment of a power amplifier circuit using amplifier combining;

FIG. 40 is a block diagram of an embodiment of a power amplifier circuit using multiple channelling;

FIG. 41 is a block diagram of an embodiment of a power amplifier circuit using predistortion;

FIG. 42 is a block diagram of an embodiment of a power amplifier circuit using adaptive predistortion;

FIG. 43 is a block diagram of an embodiment of a power amplifier circuit using feedforward;

FIG. 44 is a block diagram of an embodiment of a power amplifier circuit using adaptive feedforward; and

FIG. 45 is a block diagram of an embodiment of a power amplifier circuit using envelope feedback.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

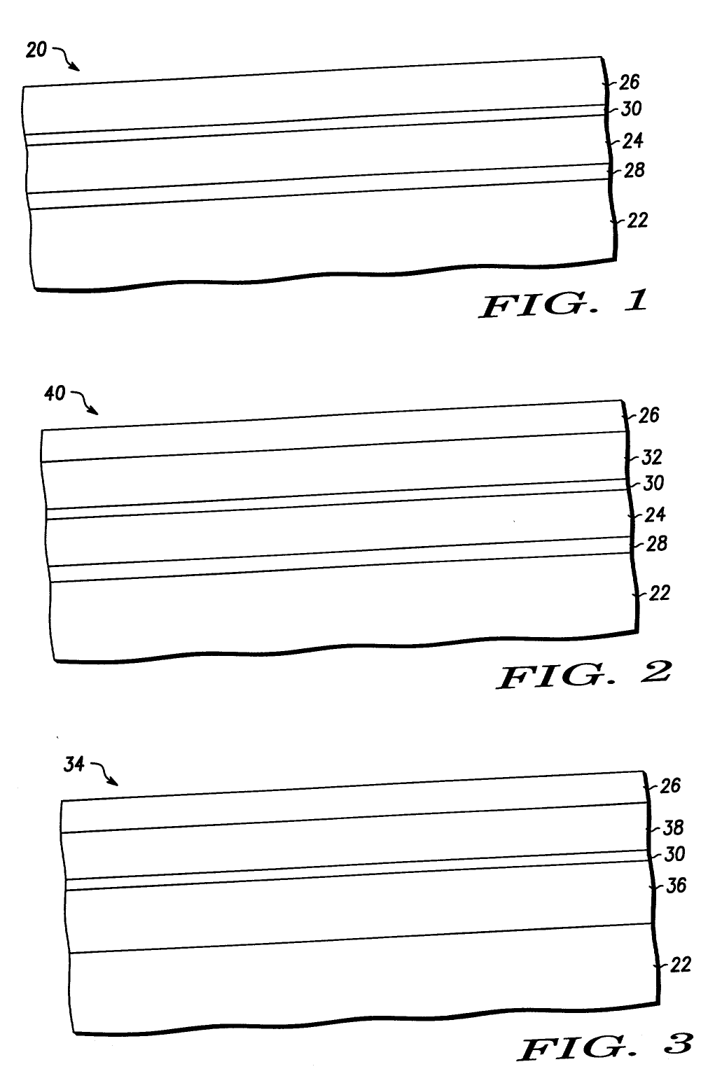

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5 -5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or bariumoxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

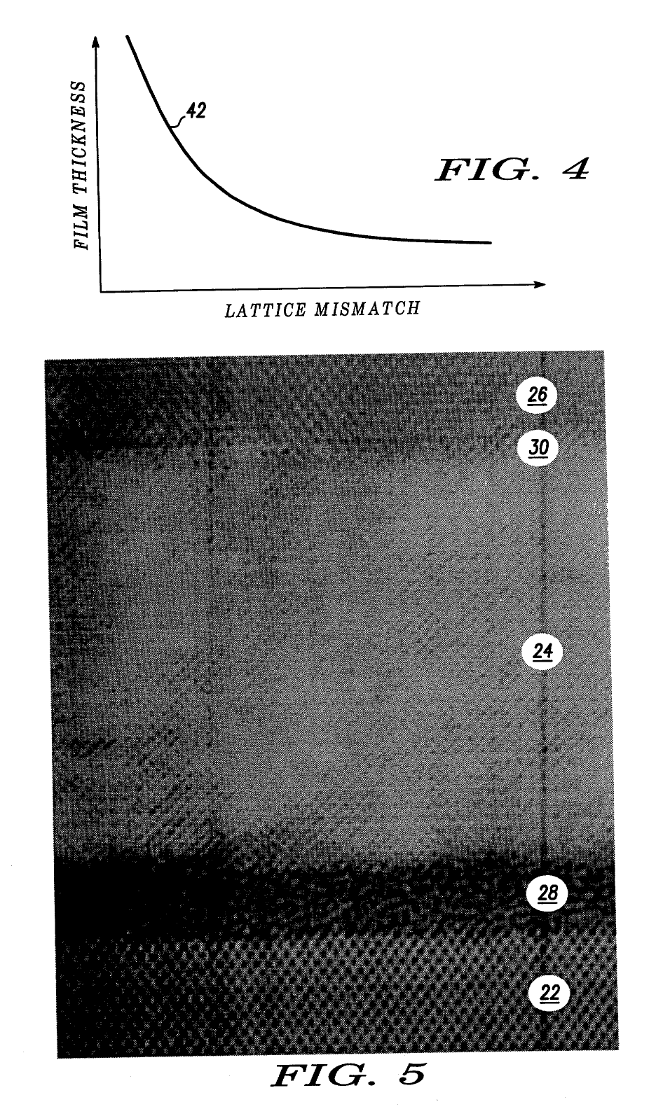

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

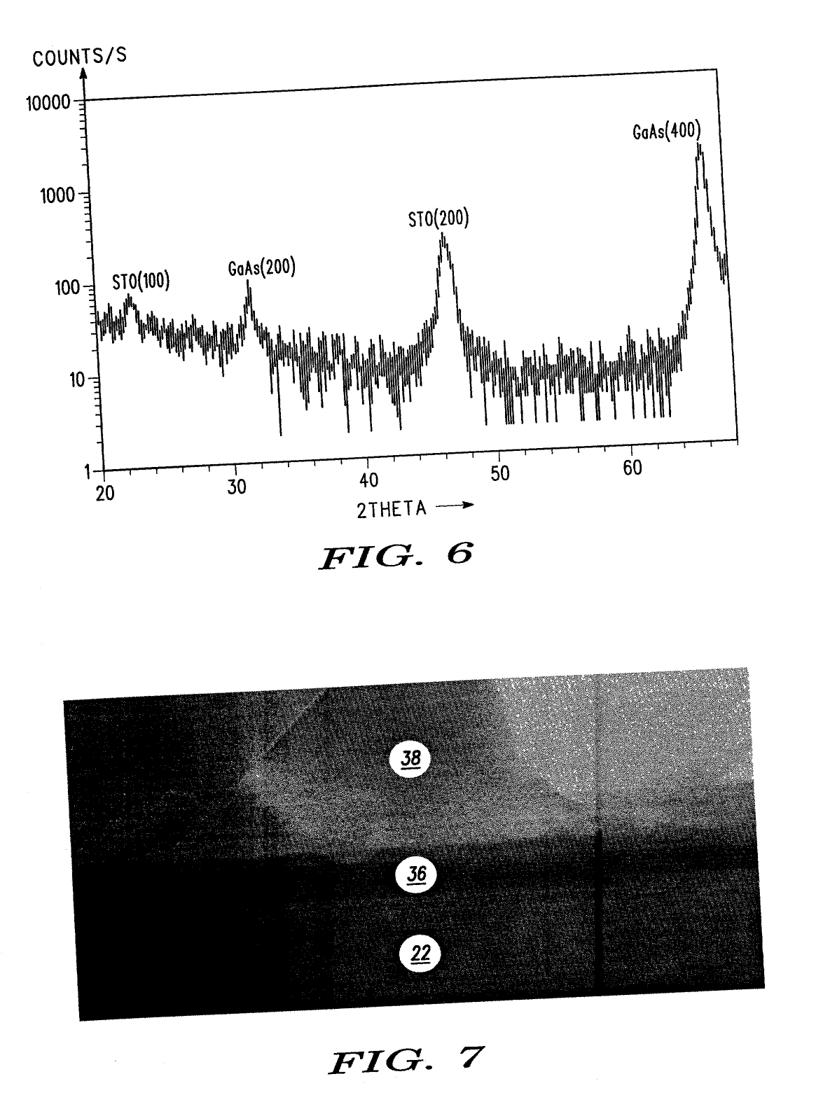

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

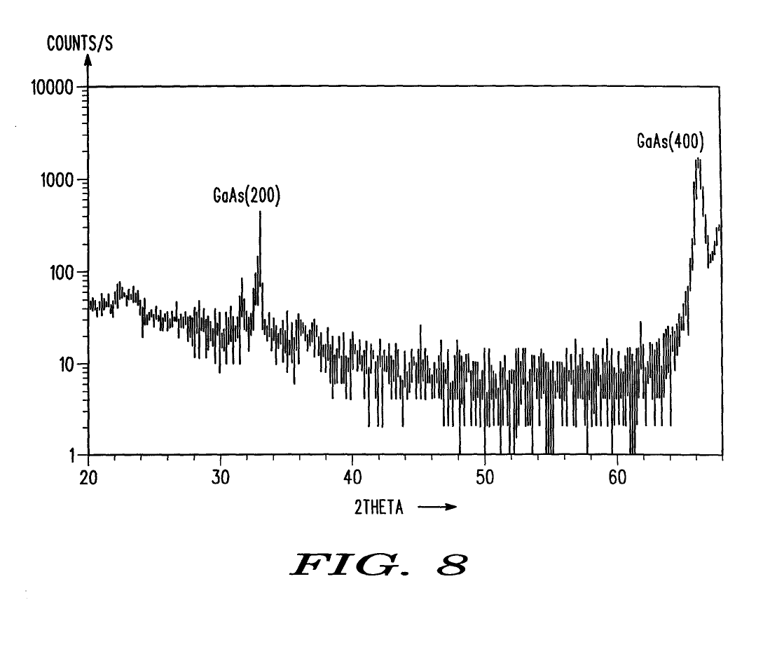

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

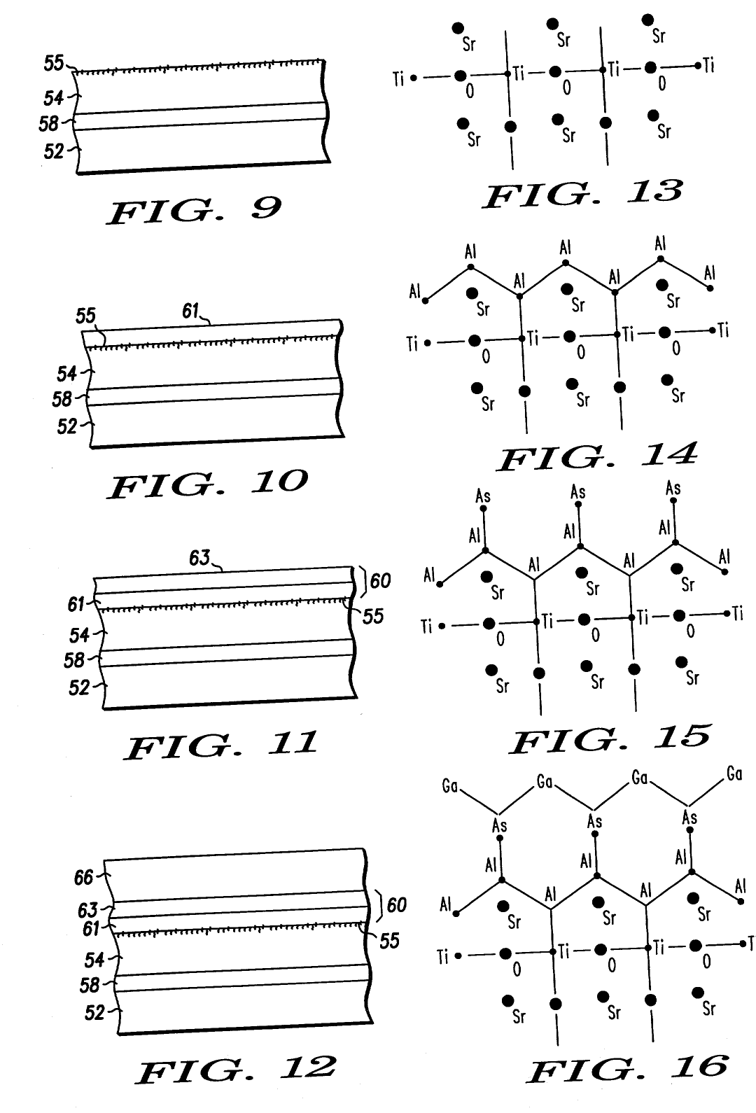

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

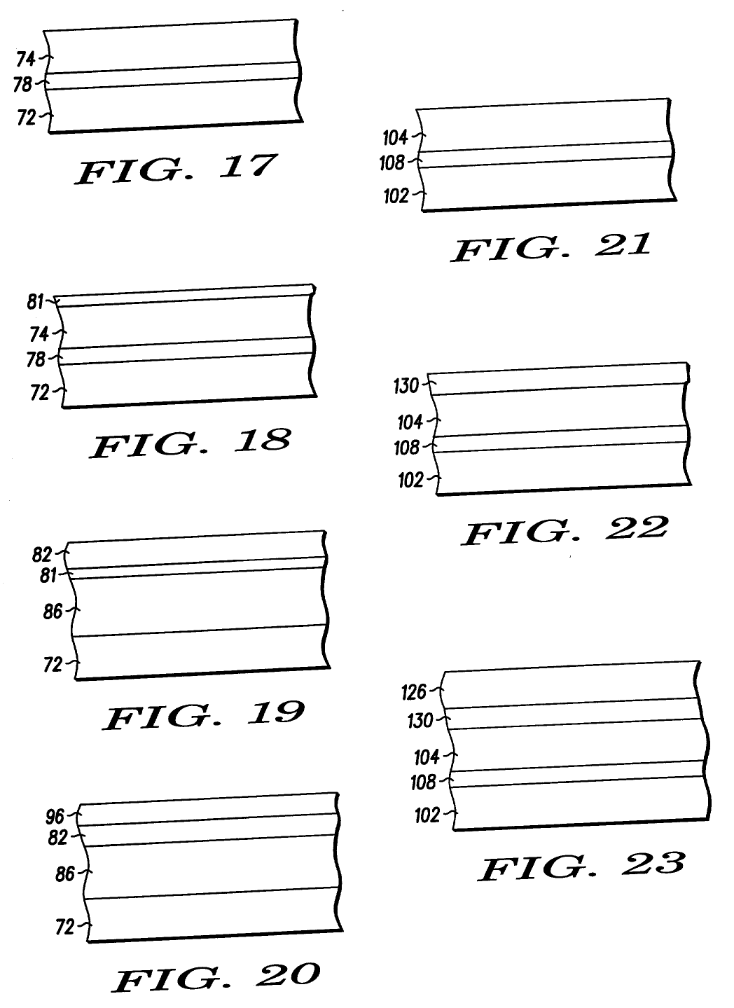

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂.

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba₁₋ₓTiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba₁₋ₓTiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

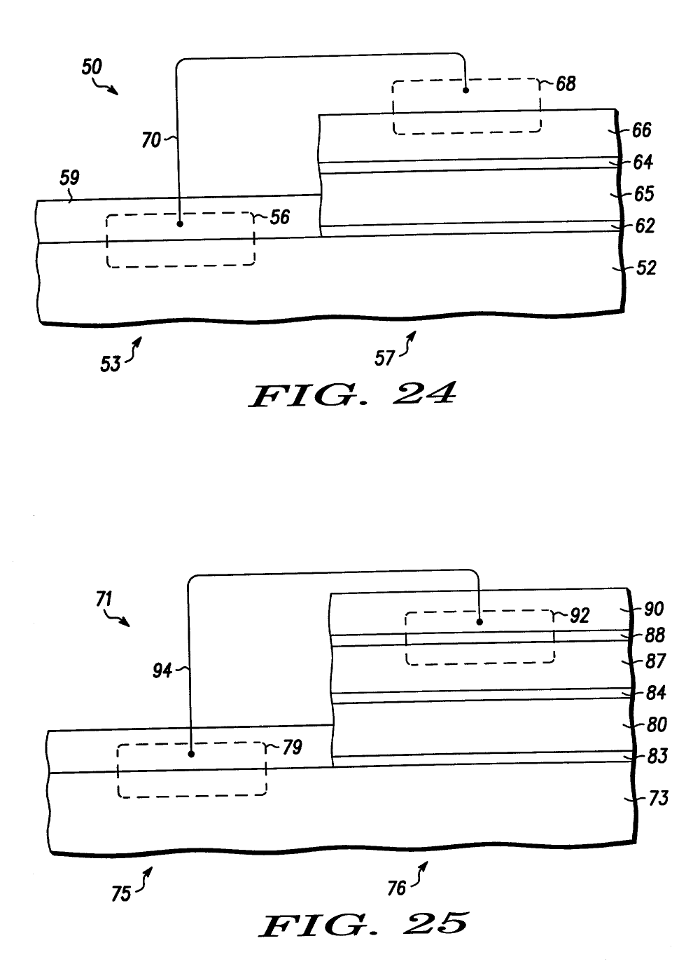

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

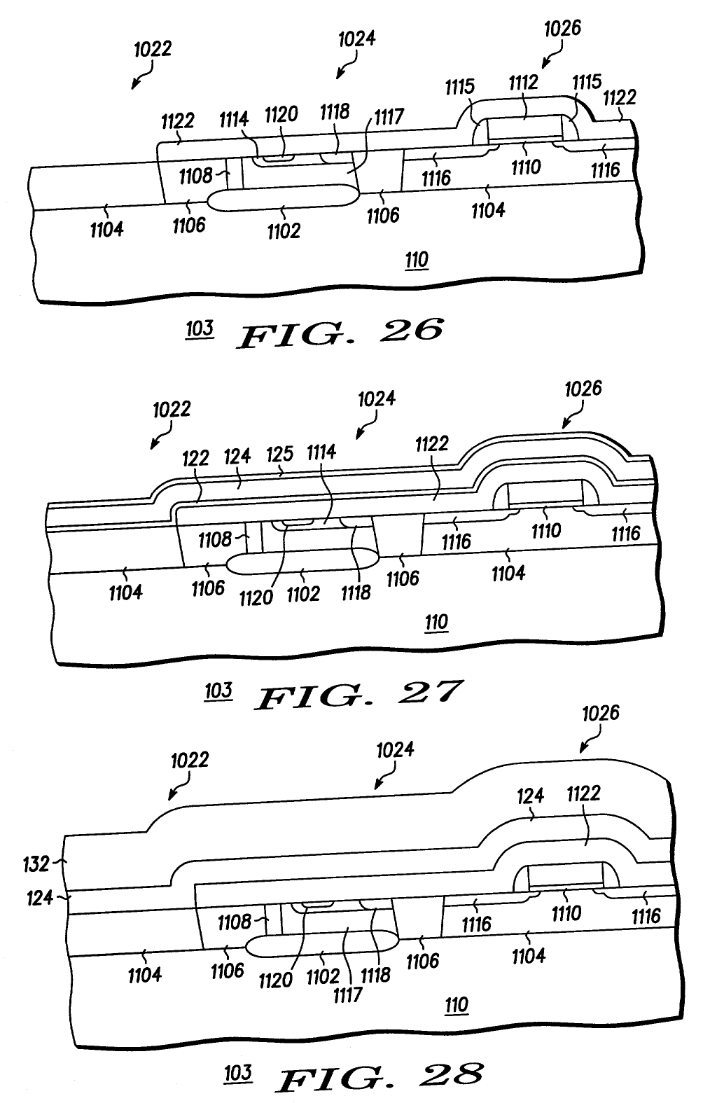

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

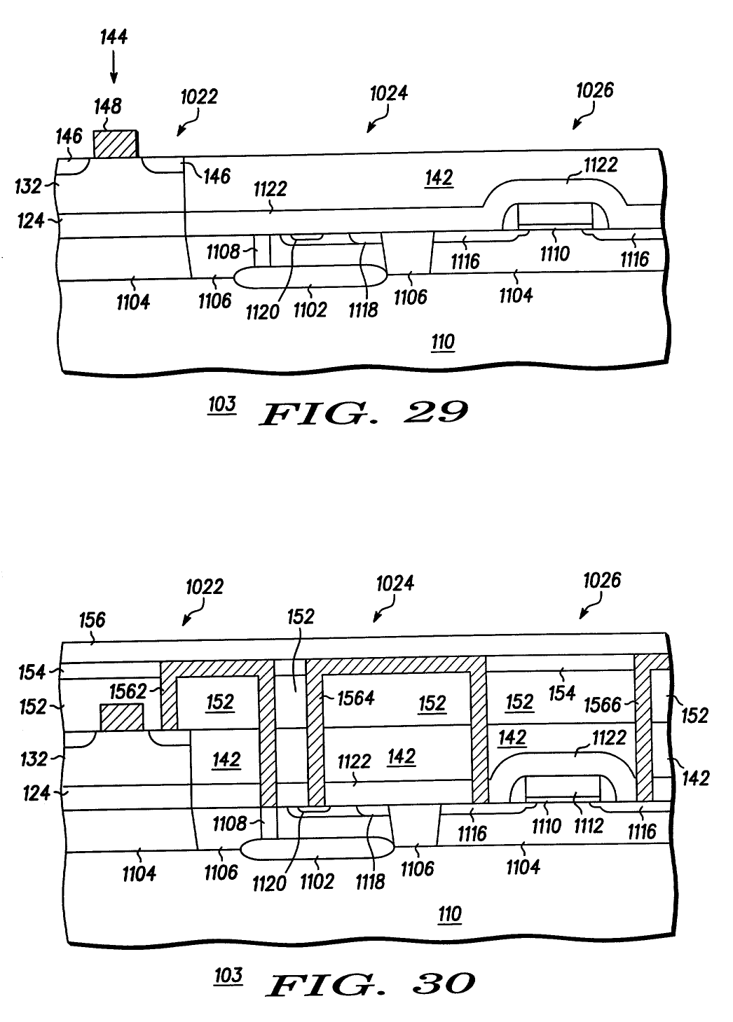

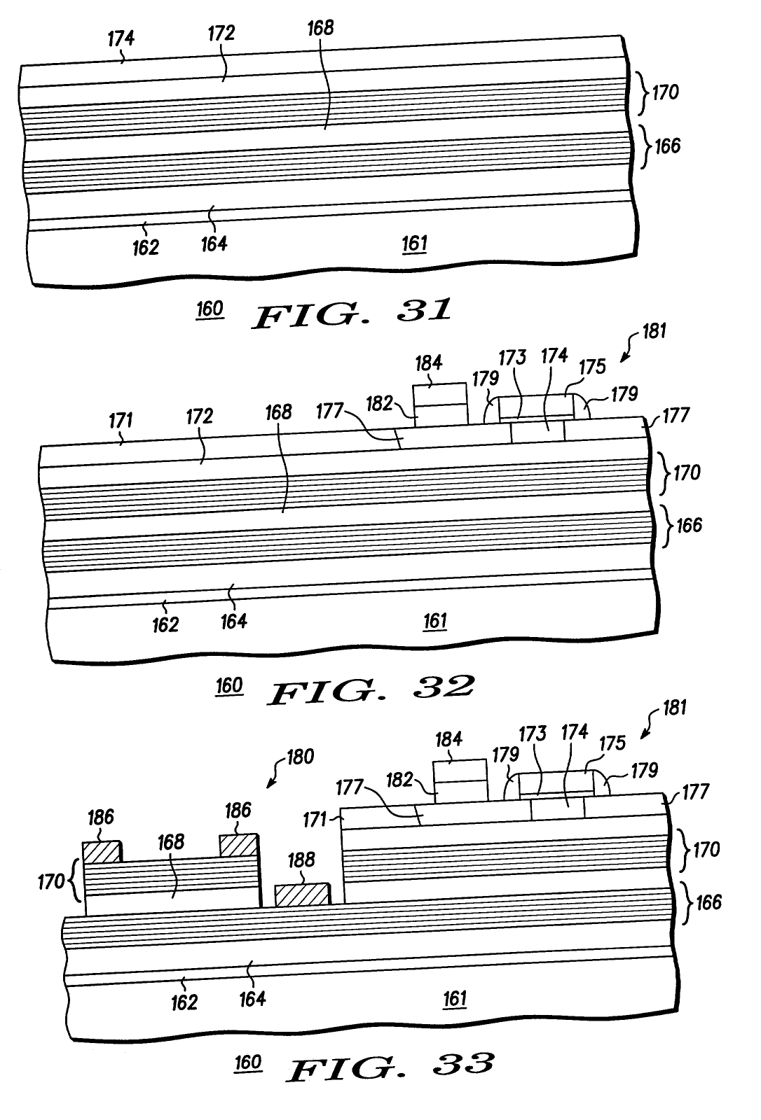

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1 120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

In still another embodiment, an integrated circuit can be formed such that it includes an optical laser in a compound semiconductor portion and an optical interconnect (waveguide) to a MOS transistor within a Group IV semiconductor region of the same integrated circuit. FIGS. 31-37 include illustrations of one embodiment.

FIG. 31 includes an illustration of a cross-section view of a portion of an integrated circuit 160 that includes a monocrystalline silicon wafer 161. An amorphous intermediate layer 162 and an accommodating buffer layer 164, similar to those previously described, have been formed over wafer 161. Layers 162 and 164 may be subject to an annealing process as described above in connection with FIG. 3 to form a single amorphous accommodating layer. In this specific embodiment, the layers needed to form the optical laser will be formed first, followed by the layers needed for the MOS transistor. In FIG. 31, the lower mirror layer 166 includes alternating layers of compound semiconductor materials. For example, the first, third, and fifth films within the optical laser may include a material such as gallium arsenide, and the second, fourth, and sixth films within the lower mirror layer 166 may include aluminum gallium arsenide or vice versa. Layer 168 includes the active region that will be used for photon generation. Upper mirror layer 170 is formed in a similar manner to the lower mirror layer 166 and includes alternating films of compound semiconductor materials. In one particular embodiment, the upper mirror layer 170 may be p-type doped compound semiconductor materials, and the lower mirror layer 166 may be n-type doped compound semiconductor materials.

Another accommodating buffer layer 172, similar to the accommodating buffer layer 164, is formed over the upper mirror layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 3 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

In FIG. 32, the MOS portion is processed to form electrical components within this upper monocrystalline Group IV semiconductor layer 174. As illustrated in FIG. 32, a field isolation region 171 is formed from a portion of layer 174. A gate dielectric layer 173 is formed over the layer 174, and a gate electrode 175 is formed over the gate dielectric layer 173. Doped regions 177 are source, drain, or source/drain regions for the transistor 181, as shown. Sidewall spacers 179 are formed adjacent to the vertical sides of the gate electrode 175. Other components can be made within at least a part of layer 174. These other components include other transistors (n-channel or p-channel), capacitors, transistors, diodes, and the like.

A monocrystalline Group IV semiconductor layer is epitaxially grown over one of the doped regions 177. An upper portion 184 is P+ doped, and a lower portion 182 remains substantially intrinsic (undoped) as illustrated in FIG. 32. The layer can be formed using a selective epitaxial process. In one embodiment, an insulating layer (not shown) is formed over the transistor 181 and the field isolation region 171. The insulating layer is patterned to define an opening that exposes one of the doped regions 177. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping. Regardless how the P+ upper portion 184 is formed, the insulating layer is then removed to form the resulting structure shown in FIG. 32.

The next set of steps is performed to define the optical laser 180 as illustrated in FIG. 33. The field isolation region 171 and the accommodating buffer layer 172 are removed over the compound semiconductor portion of the integrated circuit. Additional steps are performed to define the upper mirror layer 170 and active layer 168 of the optical laser 180. The sides of the upper mirror layer 170 and active layer 168 are substantially coterminous.

Contacts 186 and 188 are formed for making electrical contact to the upper mirror layer 170 and the lower mirror layer 166, respectively, as shown in FIG. 33. Contact 186 has an annular shape to allow light (photons) to pass out of the upper mirror layer 170 into a subsequently formed optical waveguide.

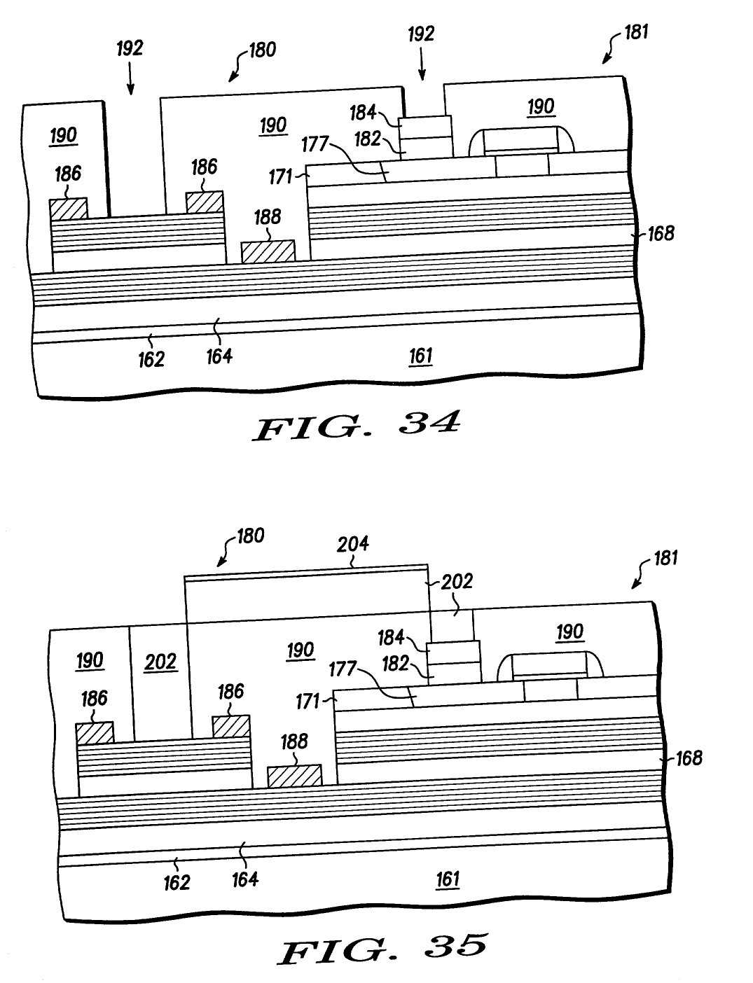

An insulating layer 190 is then formed and patterned to define optical openings extending to the contact layer 186 and one of the doped regions 177 as shown in FIG. 34. The insulating material can be any number of different materials, including an oxide, nitride, oxynitride, low-k dielectric, or any combination thereof. After defining the openings 192, a higher refractive index material 202 is then formed within the openings to fill them and to deposit the layer over the insulating layer 190 as illustrated in FIG. 35. With respect to the higher refractive index material 202, “higher” is in relation to the material of the insulating layer 190 (i.e., material 202 has a higher refractive index compared to the insulating layer 190). Optionally, a relatively thin lower refractive index film (not shown) could be formed before forming the higher refractive index material 202. A hard mask layer 204 is then formed over the high refractive index layer 202. Portions of the hard mask layer 204, and high refractive index layer 202 are removed from portions overlying the opening and to areas closer to the sides of FIG. 35.

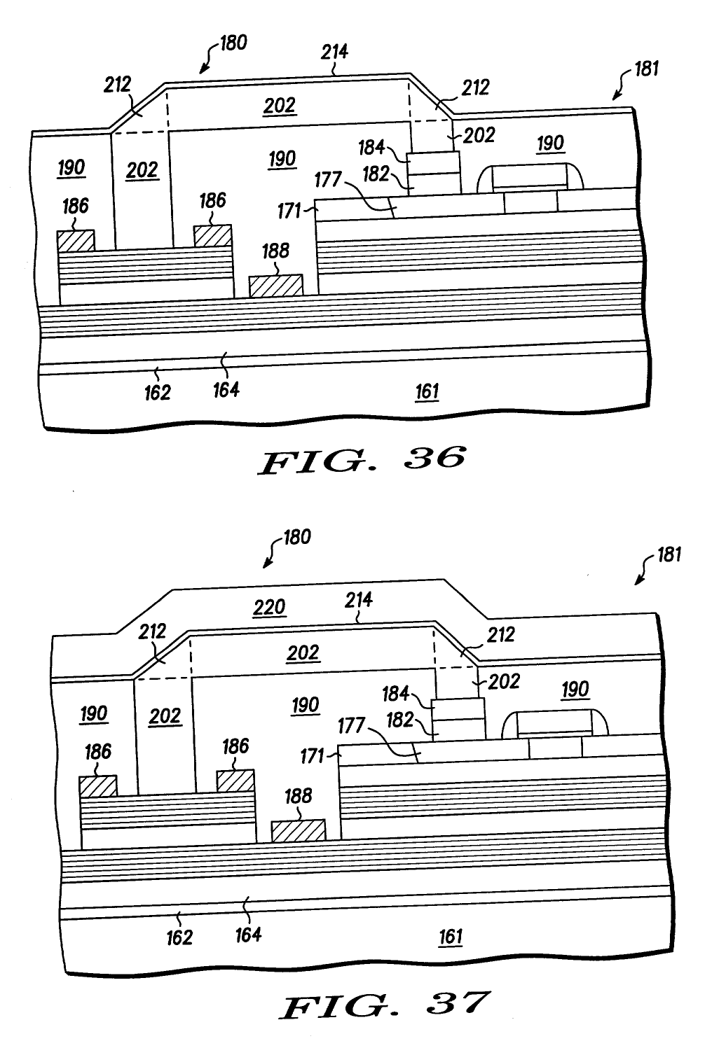

The balance of the formation of the optical waveguide, which is an optical interconnect, is completed as illustrated in FIG. 36. A deposition procedure (possibly a dep-etch process) is performed to effectively create sidewalls sections 212. In this embodiment, the sidewall sections 212 are made of the same material as material 202. The hard mask layer 204 is then removed, and a low refractive index layer 214 (low relative to material 202 and layer 212) is formed over the higher refractive index material 212 and 202 and exposed portions of the insulating layer 190. The dash lines in FIG. 36 illustrate the border between the high refractive index materials 202 and 212. This designation is used to identify that both are made of the same material but are formed at different times.

Processing is continued to form a substantially completed integrated circuit as illustrated in FIG. 37. A passivation layer 220 is then formed over the optical laser 180 and MOSFET transistor 181. Although not shown, other electrical or optical connections are made to the components within the integrated circuit but are not illustrated in FIG. 37. These interconnects can include other optical waveguides or may include metallic interconnects.

In other embodiments, other types of lasers can be formed. For example, another type of laser can emit light (photons) horizontally instead of vertically. If light is emitted horizontally, the MOSFET transistor could be formed within the substrate 161, and the optical waveguide would be reconfigured, so that the laser is properly coupled (optically connected) to the transistor. In one specific embodiment, the optical waveguide can include at least a portion of the accommodating buffer layer. Other configurations are possible.

Clearly, these embodiments of integrated circuits having compound semiconductor portions and Group IV semiconductor portions, are meant to illustrate what can be done and are not intended to be exhaustive of all possibilities or to limit what can be done. There is a multiplicity of other possible combinations and embodiments. For example, the compound semiconductor portion may include light emitting diodes, photodetectors, diodes, or the like, and the Group IV semiconductor can include digital logic, memory arrays, and most structures that can be formed in conventional MOS integrated circuits. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., the optical laser illustrated in FIG. 33), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is configured to communicate with circuitry external to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections with the external electronic circuitry. The composite integrated circuit may have internal optical communications connections for connecting the processing circuitry in the composite integrated circuit to the electrical connections with the external circuitry. Optical components in the composite integrated circuit may provide the optical communications connections which may electrically isolate the electrical signals in the communications connections from the processing circuitry. Together, the electrical and optical communications connections may be for communicating information, such as data, control, timing, etc.

A pair of optical components (an optical source component and an optical detector component) in the composite integrated circuit may be configured to pass information. Information that is received or transmitted between the optical pair may be from or for the electrical communications connection between the external circuitry and the composite integrated circuit. The optical components and the electrical communications connection may form a communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communicating synchronization information.

For clarity and brevity, optical detector components that are discussed below are discussed primarily in the context of optical detector components that have been formed in a compound semiconductor portion of a composite integrated circuit. In application, the optical detector component may be formed in many suitable ways (e.g., formed from silicon, etc.).

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well-protected by circuitry to prevent harmful external signals from reaching the composite integrated circuit. A communications ground may be isolated from the ground signal in communications connections that use a ground communications signal.

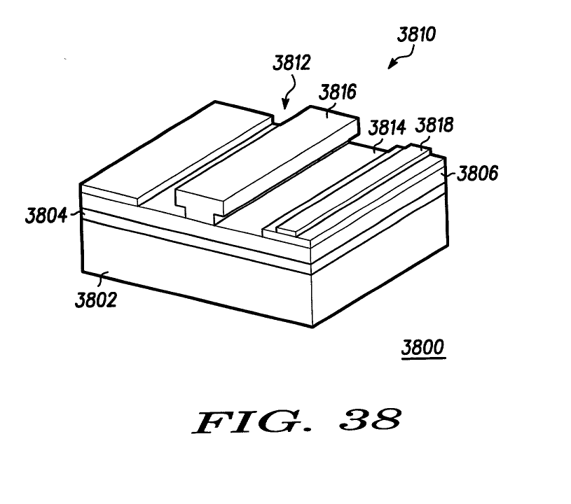

FIG. 38 is a cross sectional view of a semiconductor structure 3800. The semiconductor structure 3800 permits combination of silicon devices and compound semiconductor devices on a single structure such as a monolithic integrated circuit. The semiconductor structure 3800 may be manufactured in accordance with any of the embodiments described herein. In one exemplary embodiment, however, the semiconductor structure 3800 is formed starting with a monocrystalline silicon substrate 3802. An interfacial or buffer layer 3804 overlies the silicon substrate 3802. An amorphous oxide material overlies the monocrystalline silicon substrate and a monocrystalline perovskite oxide material overlies the amorphous oxide material. A monocrystalline compound semiconductor material 3806 overlies the monocrystalline perovskite oxide material. In some embodiments, portions of the silicon substrate 3802 may be exposed and expitaxial, monocrystalline silicon grown so as to be generally coplanar with the monocrystalline compound semiconductor material 3806. The monocrystalline compound semiconductor material 3806 and the epitaxial monocrystalline silicon may be patterned using conventional photolithographic techniques to define devices such as a transistor 3810 including source/drain regions 3812, 3814. Materials such as metal 3816 and polysilicon may be deposited and patterned to form gates for the transistors and interconnect materials such as metal 3818 may be further deposited to connect associated devices and circuits.

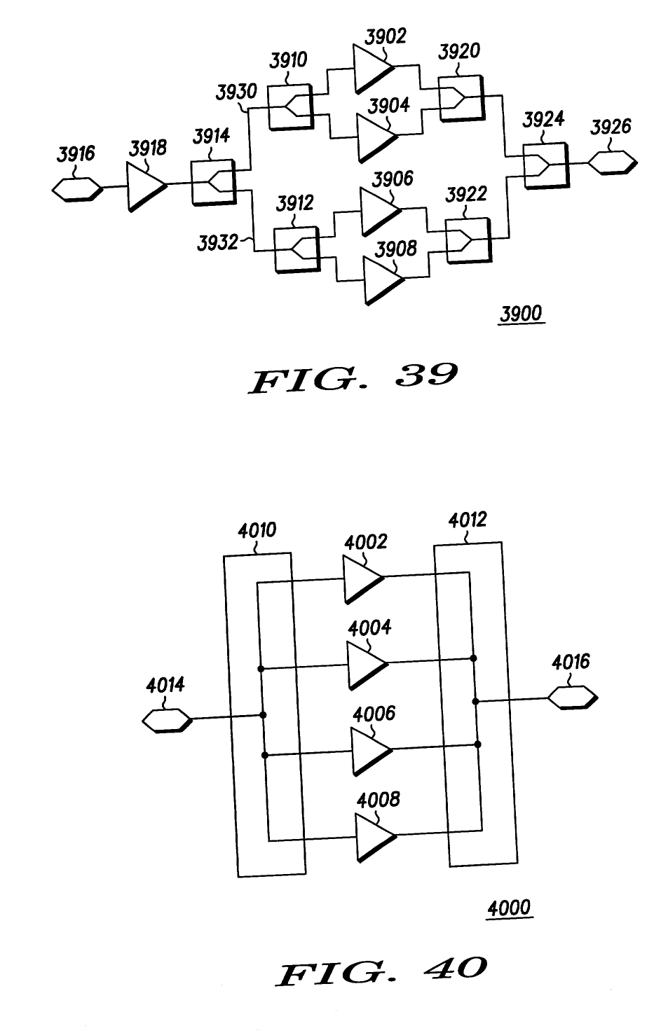

FIGS. 39-45 illustrate embodiments of power amplifier circuits formed using any of the techniques and structures described herein. FIG. 39 is a block diagram of an embodiment of a power amplifier circuit 3900 using an amplifier combining technique. The power amplifier 3900 can be constructed according to any of the embodiments illustrated above. These embodiments utilize high performance compound semiconductor materials grown on a low cost substrate such as silicon to integrate multiple functions required for producing a highly linear power amplifier in a monolithic system integrated circuit. These embodiments thereby achieve significant improvements in output power, linearity, efficiency, power handling and cost by using the material most suited for the frequency and application of interest, all in a monolithic environment. By growing the compound semiconductor material on a low cost substrate that can be manufactured and handled in large sizes, significant reductions in complexity, cost and improvement in performance can be achieved at the system level.

The power amplifier 3900 includes a plurality of individual amplifiers 3902, 3904, 3906, 3908. Further, the power amplifier 3900 includes power splitters/combiners 3910, 3912, 3914 coupled between an input 3916 and the plurality of amplifiers. In the illustrated embodiment, the power amplifier 3900 also includes an input amplifier 3918 coupled between the input 3916 and a power splitter/combiner 3914. The power amplifier 3900 further includes power splitters/combiners 3920, 3922, 3924 coupled between the amplifiers 3902, 3904, 3906, 3908 and an output 3926.

The input amplifier 3918 receives an input signal from the input 3916. The input signal may be, for example, a radio frequency (RF) time varying signal. The amplifier 3918 amplifies the signal and provides an amplified input signal at its output. The amplifier 3918 in one embodiment provides near unity gain and operates as a buffer amplifier, providing high input impedance for the power amplifier 3900. In other embodiments, the input amplifier 3918 may be omitted or may be implemented as a driver amplifier to drive the other amplifiers 3902, 3904, 3908, 3908 of the power amplifier. The input amplifier 3918 may provide other levels of amplification or signal processing as well.

The power splitter/combiner 3914 divides the amplified input signal from the input amplifier 3918 into two signals. A first signal is provided to a first circuit path 3930 and a second signal is provided to a second signal path 3932. The signal paths 3930, 3932 maybe, for example, transmission lines or other signal conductors. The power splitter/combiner 3914 preferably divides the input signal into two signals having substantially equal power and equal phase or a fixed phase offset. Any suitable power splitter may be used to embody a power splitter/combiner 3914. Conventional power splitters generally include compound semiconductor devices such as transistors manufactured from gallium arsenide, indium phosphide, or other compound semiconductor material. In the illustrated embodiment, the power splitters/combiners 3910, 3942, 3914 are shown with the same schematic symbol as the symbol shown for power splitters/combiners 3920, 3922, 3924. In some embodiments, the same devices may be used for both splitting and combining signals simply by connecting the devices differently in the circuit. In other embodiments, it may be preferred to use a particular type of power splitter or power combiner in place of the power splitters/combiners shown in FIG. 3900.

The power splitters/combiners 3910, 3912 receive the split power signal from the power splitter 3914. Each of the power splitters 3910, 3912 produces two output signals in response to a single received input signal. Each of the output signals has substantially one-half the power of the input signal. Otherwise, the output signals from the power splitters/combiners 3910, 3912, 3914 are substantially identical to the input signals.

The output signals from the power splitters 3910, 3912 are provided as input signals to the individual amplifiers 3902, 3904, 3906, 3908. Each of these individual amplifiers in the illustrated embodiment is substantially identical. The amplifiers may be implemented using any suitable amplifier design. Conventional amplifiers suitable for radio frequency amplification generally include a plurality of compound semiconductor devices, such as gallium arsenide transistors and other devices. These compound semiconductor devices provide the high frequency operation and low power consumption required in typical applications.

Each of the amplifiers 3902, 3904, 3906, 3908 has a plurality of modes of operation, including linear mode, saturation mode and other non-linear modes where gain is compressed but operation is not fully saturated. Preferably, each of the amplifiers is biased so that it operates in linear mode or in its linear region of operation. The linear region is preferable because minimal signal distortion is introduced by the amplifier operating in linear mode. In saturation mode or a non-linear mode, some distortion can be introduced by the amplifier, particularly for high frequency or high power input signals. The output power available from an individual amplifier may be reduced in the linear region compared with the saturation region, but the output signal distortion is less as well. In the illustrated embodiment, the output power gain is obtained by providing additional amplifiers. Thus, while fewer amplifiers may provide the same output power to the output 3926, by dividing the input power among four amplifiers in the illustrated embodiment, best performance is obtained including minimal gain and phase distortion. Each of the amplifiers 3902, 3904, 3906, 3908 thus produces an amplified output signal.

The amplified output signals from the amplifiers 3902, 3904 are combined in power splitter/combiner 3920. Similarly, the amplified output signals from the amplifiers 3906, 3908 are combined in the power splitter/combiner 3922. Similarly, output signals from the power splitter/combiner 3920 and the power splitter/combiner 3922 are combined in the power splitter/combiner 3924 and provided as an output signal at the output 3926. As noted, in the illustrated embodiment, the power splitters/combiners 3920, 3922, 3924 are identical to the power splitters/combiners 3910, 3912, 3914, but operated as power combiners. This embodiment provides symmetry among all the circuit paths from the input 3916 to the output of 3926, minimizing any distortion or noise that may be introduced on any circuit path separate from any other circuit path. In alternative embodiments, another type of power combiner may be substituted for the power splitters/combiners 3920, 3922, 3924.

Thus, the amplifiers 3902, 3904, 3906, 3908 are each operated in a linear mode. The power splitters/combiners 3910, 3912, 3914 form a power splitting circuit coupled to the input 3916 and the power amplifiers 3902, 3904, 3906, 3908 and configured to provide amplifier signals to each of the power amplifiers. The power splitters divide signal power of the signal for power amplification among the power amplifiers. The power splitters/combiners 3920, 3922, 3924 form a power combining circuit coupled with the power amplifiers and configured to combine output signals from the power amplifiers, producing an output signal at the output 3926.

In the illustrated embodiment, the input signal is divided into four substantially identical paths or legs for power amplification. In alternative embodiments, fewer or more power division and power amplification circuit legs may be provided. The choice as to number of legs may be made based upon the power amplification available in the amplifiers, the operational features of the amplifiers in their linear mode, and the total power amplification required by the power amplifier 3900. In all embodiments, it is preferred that power be divided evenly among the various amplification legs.

FIG. 40 is a block diagram of an embodiment of a power amplifier circuit 4000 using multiple channeling. The power amplifier 4000 includes an amplifier 4002, an amplifier 4004, an amplifier 4006, and an amplifier 4008. The power amplifier 4000 further includes an input demultiplexer 4010 and an output multiplexer 4012. The power amplifier circuit 4000 has an input 4014 and an output 4016.

The power amplifier 4000 is suitable for amplifying a variety of signals, including a multi-carrier signal. The multi-carrier signal is received at the input 4014, amplified in power amplifier 4000 and an amplified multi-carrier signal is provided at the output 4016. The multi-carrier signal includes a plurality of carriers, each carrier having a carrier frequency, designated as f1, f2, f3, f4.

The amplifiers 4002, 4004, 4006, 4008 preferably provide substantially identical amplification of signals received at their respective inputs. Since each amplifier operates on a signal at a different frequency, the individual amplifiers may be tuned or biased to provide appropriate performance at the carrier frequency. In general, the amplifiers are preferably identical.

The input demultiplexer 4010 has an input coupled to the input 4014 and four outputs, each output being coupled with the input of a respective amplifier 4002, 4004, 4006, 4008. The input demultiplexer 4010 divides or separates or channelizes the multi-carrier signal received at the input 4014 into its constituent carriers. This carrier separation operation may be done by band pass filtering the multi-carrier signal or by any other suitable method. The individual carriers are provided at their respective frequencies, f1, f2, f3, f4 to the respective amplifiers 4002, 4004, 4006, 4008. In an alternative embodiment, the input demultiplexer 4010 may include a matching circuit to match the input impedance of the amplifiers 4002, 4004, 4006, 4008.

After amplification, amplified signals are provided to the output multiplexer 4012 for recombining. The output multiplexer 4012 has four inputs, each input being coupled with an output of a respective amplifier. The output multiplexer further has an output coupled to the output 4016 of the power amplifier 4000. The operation of the output multiplexer 4012 may be performed by any suitable circuit or device. In an alternative embodiment, the output multiplexer 4012 may include a matching circuit to match the output impedance of the amplifiers 4002, 4004, 4006, 4008.

Thus, the power amplifier 4000 is suitable for amplifying an input signal having two or more frequency components. It will be understood that any appropriate number of amplifiers may be provided, depending on the number of carriers present in the input signal. The input multiplexer 4010 and the output multiplexer 4012 may be expanded or contracted as appropriate to process the multiply carriers.

The channelized power amplifier 4000 is particularly suitable for reducing intermodulation distortion during amplification of the input signal. Intermodulation distortion is the production of noise at frequencies which are products of carrier frequencies or harmonics of carrier frequencies. By separating or channelizing the carriers into separate amplification paths, intermodulation is reduced or eliminated.

Further, to implement the power amplifier 4000 with reduced intermodulation, a type of amplifier may be used for the amplifiers 4002, 4004, 4006, 4008 which has poor harmonic or intermodulation response. Since the individual amplifiers are processing narrow-band or single carrier signals, the harmonic or intermodulation response of the individual amplifiers is reduced in importance. An embodiment employing amplifiers having poor harmonic or intermodulation response may be beneficial for reducing the overall cost and complexity of the power amplifier 4000.

Preferably, the amplifiers 4002, 4004, 4006, 4008 are integrated in a common semiconductor structure or monolithic integrated circuit with the input multiplexer 4010 and the output multiplexer 4012. Such integration reduces noise and distortion introduced into the signal, reduces parts count for the overall system and reduces power dissipation for the system as well. Such integration also provides improvement in gain.

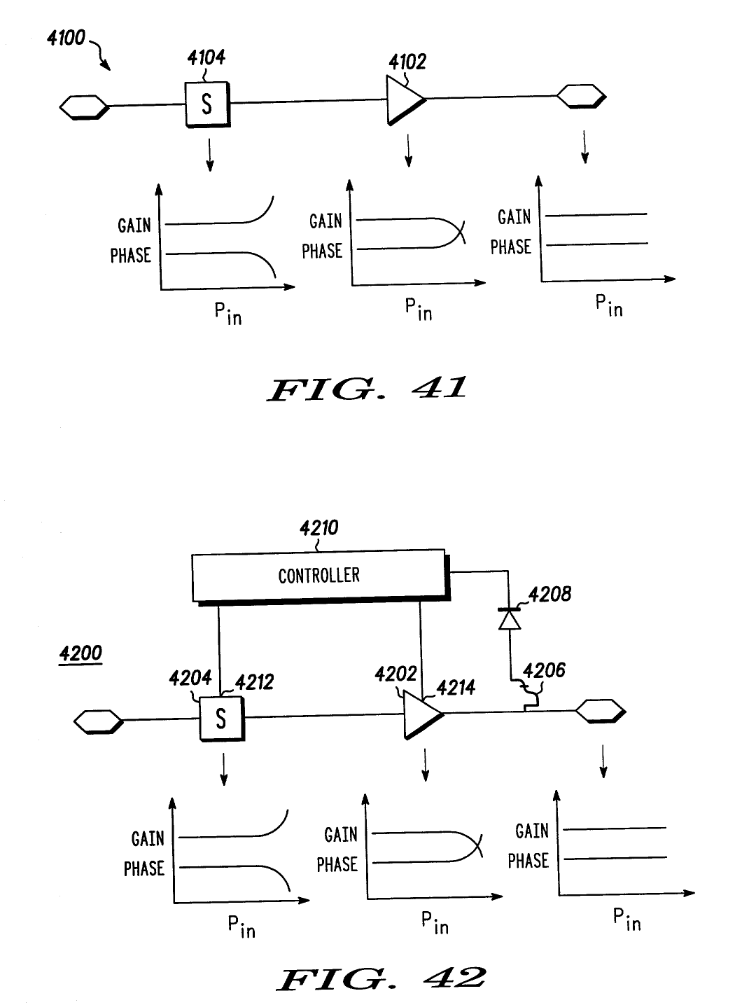

FIG. 41 is a block diagram of an embodiment of a power amplifier circuit 4100 using predistortion. The power amplifier circuit 4100 includes an amplifier 4102 and a linearizer 4104. To provide a linear response for the power amplifier circuit 4100, a response for the linearizer 4104 is chosen to complement the response of the amplifier 4102. The resulting combination of the amplifier 4102 and the linearizer 4104 produces a substantially linear response.

Exemplary response curves are illustrated for the amplifier 4102 and the linearizer 4104 in FIG. 41. In the response curves, gain and phase are plotted as a function of input power, Pᵢₙ. As can be seen in FIG. 41, the gain response of the amplifier 4102 rolls off or decreases at relatively high input power levels. Similarly, the phase response increases at relatively high input power levels. Note that these response curves are exemplary only. The amplifiers will have individual response characteristics, which may differ from those illustrated in FIG. 41.

Thus, if the amplifier 4102 was operated alone as a power amplifier, the amplified signal would demonstrate the response illustrated in the frequency response curves for the amplifier 4102. At high input power levels, distortion would be introduced because of the non-constant response for gain and phase of the amplifier 4102.

Accordingly, the gain and phase response for the linearizer 4102 is chosen to compensate for the distortion introduced by the amplifier 4102. Thus, in the exemplary embodiment of FIG. 41, the linearizer 4102 has a gain response which increases with increasing input power. Similarly, the linearizer 4104 has a phase response which decreases with increasing input power. Moreover, the gain and phase response substantially compensate for or cancel out the distortion introduced by the amplifier 4102 so that when the amplifier 4102 and linearizer 4104 are operated in series, the combined gain and phase response are as shown at the right of FIG. 41. The gain and phase for the linearized, amplified output signal are substantially constant across all input power levels.

Thus, the linearizer 4104 forms an associated linearization circuit for the power amplifier 4102. The linearizer 4104 may be constructed in any suitable manner using any suitable components. The linearizer 4104 forms a means for distorting frequency response of an input signal to compensate for distortion of the amplifier 4102. Preferably, the amplifier 4102 and the linearizer 4104 are manufactured as part of the same semiconductor structure, such as a monolithic integrated circuit. This allows the two circuits to experience substantially identical manufacturing conditions and environmental conditions, improving the complimentary match of the gain and phase response for the two circuits.

FIG. 42 is a block diagram of an embodiment of a power amplifier circuit 4200 using adaptive predistortion. The power amplifier 4200 includes an amplifier 4202 and a linearizer 4204. Further, the power amplifier 4200 also includes a coupler 4206, a detector 4208 and a control circuit 4210.

The amplifier 4202 and the linearizer 4204 may be similar to those components illustrated above in connection with FIG. 41. The amplifier 4202 has a performance illustrated by the response curves for gain and phase as a function of input power Pᵢₙ shown FIG. 42. The linearizer 4204 is maintained with a gain and phase response which complimentarily matches the gain and phase response of the amplifier 4202. In combination, the amplifier 4202 and the linearizer 4204 produce gain and phase response curves as illustrated at the right of FIG. 42.

In order to ensure that the gain and phase response remain flat as illustrated in FIG. 42, the coupler and detector are used to sample the output signal produced by the amplifier 4202. The controller 4210 is responsive to the sampled output signal to provide an adaptation signal to the linearizer 4204 and the amplifier 4202. Thus, the linearizer 4204 has a control input 4212 and the amplifier 4202 has a control input 4214. The control inputs 4212, 4214 may correspond to, for example, automatic gain control inputs or biased voltage inputs or other suitable control signal inputs.

The control circuit 4210 is configured to provide appropriate control signals to the control inputs 4212, 4214 to adapt the respective gain and phase response of the amplifier 4202 and the linearizer 4204 in order to maintain flat gain and phase response for the output signal. The control circuit 4210 may be implemented as a digital logic circuit, as a processor which responds to data and instructions stored in memory, or as a linear circuit. Since the process of determining appropriate adaptation signals or control signals for the amplifier 4202 and the linearizer 4204 is relatively complex, the controller 4210 may be well-suited for implementation as a digital control circuit such as a microprocessor. In such an implementation, the control circuit 4210 may be formed in a silicon portion of the semiconductor structure forming the power amplifier circuit 4200. Because of required frequency response and low power dissipation, the amplifier 4202 and linearizer 4204 may preferably be formed using a compound semiconductor portion of the semiconductor structure. Similarly, the coupler 4206 and the detector 4208 may be implemented in the compound semiconductor portion of the semiconductor structure. Thus, the linearizer 4204 forms a means for distorting a signal in response to the adaptation signal received at the control input 4212 from the controller 4210.

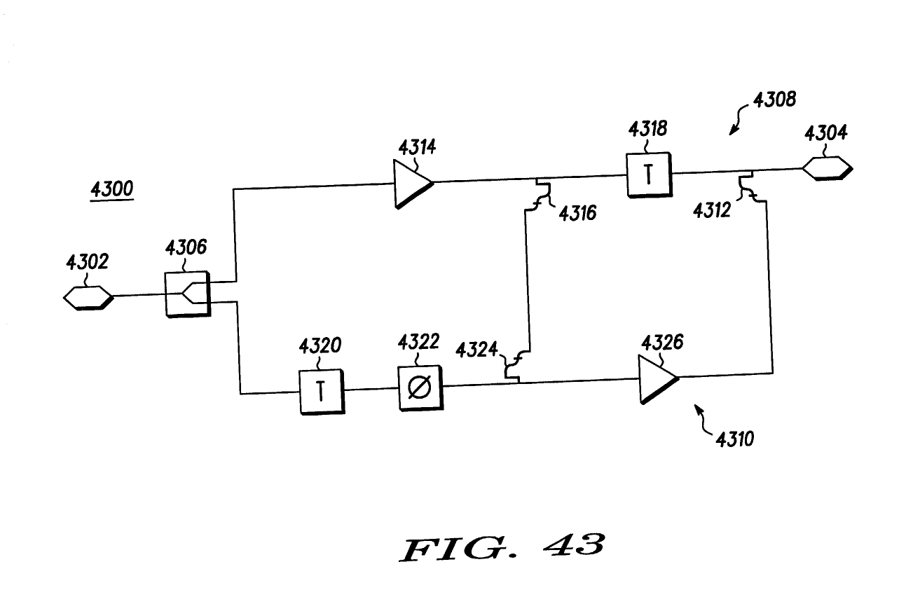

FIG. 43 is a block diagram of an embodiment of a power amplifier circuit 4300 using feedforward. The feedforward amplifier 4300 is configured to process an input signal received at an input 4302 and to produce an output signal at an output 4304. The amplifier 4300 includes a splitter 4306 coupled to the input 4302, an amplification circuit 4308 coupled to the splitter 4306, an error amplification circuit 4310 coupled with the splitter 4306, and a combiner 4312 coupled with the amplification circuit 4308 and the error amplification circuit 4310 to produce the output signal at the output 4304.

The amplification circuit 4308 includes an amplifier 4314, a coupler 4316 in series with the amplifier and a time delay circuit 4318 configured to provide an amplified, time delayed signal to the combiner 4312.

The error amplification circuit 4310 includes a time delay circuit 4320, a phase shifter 4322, a coupler 4324 and an error amplifier 4326. The coupler 4316 of the error amplification circuit 4310 extracts a portion of the signal in the amplification circuit and provides the signal portion to the coupler 4324 in the error amplification circuit 4310. The coupler 4324 combines the two signals and provides the combined signal to the error amplifier 4326. The coupler 4312 combines the amplified, time delayed signal from the time delay circuit 4318 and the signal from the error amplification circuit 4310 to produce the output signal at the output 4304.

The power splitter 4306 splits the input signal received at the input into two signals having substantially equal power, in the preferred embodiment. Any suitable power splitter may be used. In order to accommodate radio frequency signals, typically compound semiconductor devices will be used to form the power splitter 4306.

A first signal is provided by the power splitter 4306 to the amplifier 4314. The amplifier 4314 amplifies this input signal and provides an amplified signal as an output. The amplifier introduces some time delay and distortion as part of its operation. The time delayed, amplified, distorted signal is provided to the coupler 4316. The coupler 4316, in turn, passes the amplified, distorted signal to the time delay circuit 4318 and also provides a portion of the amplified, distorted signal to the coupler 4324 of the error amplification circuit 4310.

The time delay circuit 4320 of the error amplification circuit 4310 receives an input signal from the power splitter 4306. The input signal preferably, substantially matches the input signal provided by the power splitter 4306 to the amplifier 4314. The time delay circuit 4320 delays the received input signal by a predetermined time delay amount. Preferably, this time delay amount corresponds to the time delay introduced by the amplifier 4314 in the signal received from the power splitter 4306. Thus the time delay 4320 delays the receive signal by a delay equal to the group delay of the amplifier 4314.

The phase shifter 4322 shifts the phase of the time delayed signal received from the time delay circuit 4320. The phase is preferably shifted by approximately 90° so that the output signal from the phase shifter 4322 is a complement of the output signal from the amplifier 4314. The coupler 4324 combines the amplified, distorted signal from the coupler 4316 of the amplification circuit 4308 and the time delayed, complemented signal from the phase shifter 4322. The result, produced by the coupler 4324, is an error signal as the amplified signal from the amplifier 4314 is cancelled by the time delayed phase shifted signal from the phase shifter 4322. The only signal remaining after this cancellation process is the error or distortion introduced by the amplifier 4314.

The time delay circuit 4318 of the amplification circuit 4308 preferably matches the time delay introduced by the error amplifier 4326. The error amplifier 4326 amplifies the error signal to a level appropriate for cancellation with the amplified, time delayed signal produced by the time delay circuit 4318. The coupler 4312 combines the amplified, time delayed signal from the time delay circuit 4318 with the amplified error signal from the error amplifier 4326. The coupler 4312 cancels the error signal from the amplified signal, producing a substantially distortion free output signal at the output 4304.

Preferably, all of the components of the feedforward amplifier 4300 of FIG. 43 are combined in a semiconductor structure such as a monolithic integrated circuit. This allows improvements in output power, linearity, efficiency, power handling and cost by using the material most suited to the frequency and other signal requirements in a monolithic environment. One or more components of the power amplifier circuit 4300 may be fabricated using a silicon portion of the semiconductor structure or using a compound semiconductor portion of the semiconductor structure.

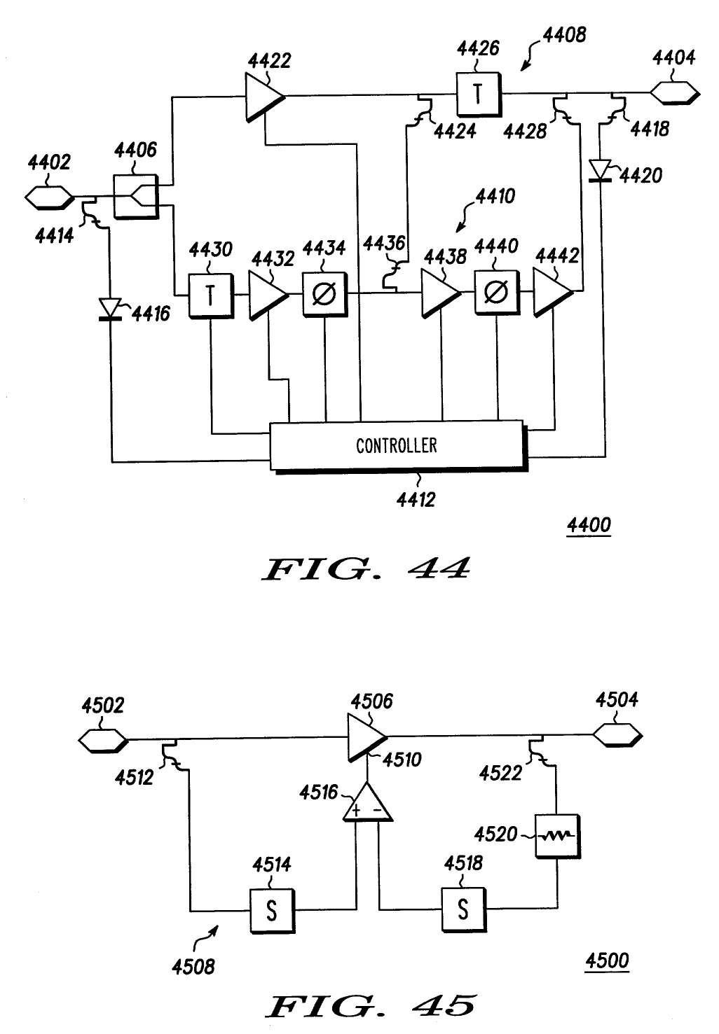

FIG. 44 is a block diagram of an embodiment of a power amplifier circuit 4400 using adaptive feedforward. The power amplifier circuit 4400 receives an input signal at an input 4402 and provides an output signal at an output of 4404. The amplifier 4400 includes a power splitter 4406, an amplification circuit 4408, an error amplification circuit 4410 and a controller 4412. The amplifier 4400 further includes a coupler 4414 coupled to the input 4402, a detector 4416 coupled to the coupler 4414, a coupler 4418 coupled to the output 4404 and a detector 4420 coupled to the coupler 4418.

The amplification circuit 4408 includes an amplifier 4422, a coupler 4424, a time delay circuit 4426 and a coupler 4428. The error amplification circuit 4410 includes a time delay circuit 4430, an amplifier 4432, a phase shifter 4434, a coupler 4436, an amplifier 4438, and a phase shifter 4440 and an amplifier 4442. The amplifier 4422, the time delay circuit 4426, the time delay circuit 4430, the amplifier 4432, the phase shifter 4434, the amplifier 4438, the phase shifter 4440, and the amplifier 4442 all have control inputs for receiving control signals from the controller 4412.

The power amplifier 4400 operates similarly to the power amplifier 4300 of FIG. 43. The power splitter 4406 divides the power of the input signal at the input 4402 between the amplification circuit 4408 and the error amplification circuit 4410. The amplifier 4422 amplifies the receive signal and produces an amplified output signal. The amplified output signal is sampled by the coupler 4424 and a portion of the amplified output signal is provided by the coupler 4424 to the coupler 4436 as a feedback signal. The time delay circuit 4426 delays the amplified circuit and provides a delayed, amplified signal to the coupler 4428.

In the error amplification circuit, the time delay circuit 4430 receives a split signal from the power splitter 4406. The time delay circuit 4430 delays the signal by a time delay substantially equal to the group delay of the power amplifier 4422. The delayed signal is amplified in the amplifier 4432. The amplified, delayed signal is complemented in the phase shifter 4434 to produce a signal which is the compliment of the amplified signal produced by the amplifier 4422, excepting the distortion introduced by the amplifier 4422. The coupler 4436 combines the complemented signal and the amplified signal to produce a signal corresponding to the error signal due to the distortion introduced by the amplifier 4422. The error signal is amplified in the amplifier 4438 and complemented in the phase shifter 4440. The complemented error signal is amplified in the error amplifier 4442 and provided to the coupler 4428. The coupler 4428 combines the error signal and the time delayed, amplified signal from the time delay circuit 4426. The resulting signal consists of solely the amplified signal with significantly reduced distortion due to distortion introduced by the amplifier 4422.

The coupler 4414 and detector 4416 sample the input signal at the input 4402 and provide the sampled input signal to the controller 4412. Similarly, the coupler 4418 and the detector 4420 sample the output signal at the output 4404 and provide the sampled output signal to the controller 4412. The controller 4412 compares the sampled output signal and the sampled input signal and controls operation of the elements of the power amplifier circuit 4400. Using control signals provided to the controlling bits of the above-listed elements of the power amplifier circuit 4400, the controller 4412 minimizes differences, other than amplification, between the output signal and the input signal.

The components of the power amplifier circuit 4400 may be formed using any suitable technology. For example, the amplifiers are preferably implemented using compound semiconductor materials such as gallium arsenide. Compound semiconductor materials provide performance at radio frequencies which may make them most suitable for implementation of these devices. In contrast, the controller 4412 implements sophisticated logic and control operations. Such operations may be best implemented using silicon devices, including memory and logic devices or even a microprocessor which operates in response to data and instructions stored in memory. Because higher levels of integration are available using silicon devices, silicon may be also preferred for reducing the overall size of a monolithic integrated circuit implementing the power amplifier circuit 4400.

Thus, the power amplifier circuit 4400 is preferably implemented in a semiconductor structure including a silicon portion in which silicon components such as the controller may be implemented and a compound semiconductor portion in which compound semiconductor elements such as couplers, detectors and amplifiers may be implemented. The semiconductor structure 3800 is just one embodiment of a suitable structure for forming such a circuit. The silicon portion used for the circuit may be the silicon substrate, epitaxial or other silicon formed on the surface of the substrate, or any combination of these.

FIG. 45 is a block diagram of an embodiment of a power amplifier circuit 4500 using envelope feedback. The power amplifier 4500 receives an input signal at an input 4502, amplifies the input signal and produces an output signal at an output 4504. The power amplifier 4500 includes an amplifier 4506 and associated linearization circuit 4508 for the power amplifier 4500.

The power amplifier 4506 may be any suitable power amplifier. Preferably, the amplifier 4506 operates at radio frequencies with minimal distortion. Amplifier 4506 includes a control input 4510 which may be adapted to receive a bias signal or an automatic gain control (AGC) signal. The linearization circuit 4508 includes a coupler 4512, a peak detector 4514, an error amplifier 4516, a peak detector 4518, an attenuator 4520 and a coupler 4522. The coupler 4512 is coupled to the input 4502 for sampling the input signal received at the input 4502. A portion of the input signal is provided by means of the coupler 4512 to the first peak detector 4514. The peak detector 4514 operates to detect peaks in the input signal and to provide a peak indication to the error amplifier 4516.

Similarly, at the output end of the power amplifier 4500, the coupler 4522 samples the output signal produced at the output of the power amplifier 4506. A portion of the output signal is attenuated in the attenuator 4520 and provided to the second peak detector 4518. The peak detector 4518 operates to identify peaks in the attenuated output signal and provide a peak indication to the error amplifier 4516. The peak indications indicate both the time when peak values of the input and output signals occur as well as the relative peak signal values of the input and output signals.

The error amplifier 4516 operates as a summer to subtract the peak detections from the input end of the power amplifier circuit 4500 and the output end of the power amplifier circuit 4500. The error amplifier 4516 produces an error signal by subtracting the peak indications. The error signal is provided to the control input 4510 of the power amplifier 4506. In response to the error signal, the transfer function of the power amplifier 4506 is modified to adjust the overall performance of the power amplifier circuit 4502. For example, if the control input 4510 is an automatic gain control input, the gain of the power amplifier 4506 will be reduced or increased in response to the error signal provided by the error amplifier 4516. The linearization circuit 4508 will operate to reduce or minimize the error between the output signal at the output 4504 and the input signal at the input 4502, allowing for amplification by the power amplifier 4506.

The components of any of the circuit illustrated or described herein or used in conjunction with the circuits described herein may be selected from silicon or compound semiconductor components and embodied in a semiconductor structure such as a monolithic integrated circuit. The material used to form a particular circuit structure may be selected based on the electrical requirements for that circuit or structure. For example, power amplifier may be preferably constructed using compound semiconductor materials such as gallium arsenide, indium phosphide or other comparable material, in order to take advantage of high frequency performance provided by such materials. Further, logic or control circuits may be implemented using a silicon portion of the semiconductor structure, since such logic circuits do not operate using radio frequency signals but may require high levels of integration to provide the necessary functionality. Silicon devices may be formed in the silicon substrate, in a layer of silicon such as epitaxial silicon grown or formed on the silicon substrate or other silicon of the monolithic integrated circuit.

From the foregoing, it can be seen that the present invention provides several embodiments of a monolithic power amplifier and associated linearization circuits. These embodiments utilize high performance compound semiconductor materials grown on a low cost substrate such as silicon. These embodiments integrate multiple functions required for development of a highly linear power amplifier in a monolithic system integrated circuit. These embodiments achieve significant improvements in output power, linearity, efficiency, power handling and cost by using the material, such as silicon or compound semiconductor material, most suited for the frequency and application of interest, all in a monolithic implementation. By growing the compound semiconductor material on a low cost silicon substrate that can be manufactured and handled in large sizes, significant reductions in complexity, cost, and improvement in performance can be achieved at the system level.

These embodiments utilize high performance compound semiconductor material grown on low cost material such as silicon to reduce complexity, reduce cost and increase performance of linear power amplifiers. These goals are achieved by integrating multiple elements of a linear power amplifier into an integrated circuit. These elements include couplers, combiners, dividers, logic processors, etc. These goals are further achieved by integrating control circuitry with high frequency circuits. These goals are further achieved by utilizing different materials on the same semiconductor structure to achieve integrated multi-process functionality, such as signal processing and control and radio frequency and high power in one circuit. Previous power amplifier circuits utilized a multitude of circuits to achieve the desired output power and linearity requirements. This previous approach increases complexity and degrades performance. The present embodiments have the ability to incorporate all the components mentioned above into a monolithic structure providing significant performance and cost improvements. Previous power amplifier circuits utilize external control and power supply circuitry. This external control circuitry adds complexity, size and cost to the overall system. The present embodiments allow for the integration of the control and supply circuitry which is typically on silicon, on a monolithic fashion in conjunction with the high frequency, compound semiconductor circuits.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a power amplifier and associated linearization circuit for the power amplifier.

2. The semiconductor structure of claim 1 wherein the linearizaton circuit comprises an error amplifier having an output coupled with a gain control input of the power amplifier to provide a gain control signal in response to a difference between an output signal and an input signal.

3. The semiconductor structure of claim 2 wherein the linearizaton circuit comprises a first input configured to sample the input signal and a second input configured to sample the output signal, the error amplifier providing an error signal to the gain control input based on the difference between the sampled input signal and the sampled output signal.

4. The semiconductor structure of claim 1 wherein the power amplifier and the associated linearization circuit are coupled in series to amplify an input signal to produce an output signal with substantially no gain or phase distortion, independent of input signal power.

5. The semiconductor structure of claim 4 wherein the linearization circuit comprises:
a predistortion linearizer coupled in series with the power amplifier.

6. The semiconductor structure of claim 4 wherein the linearization circuit comprises:
means for distorting an input signal to compensate for distortion of the power amplifier.

7. The semiconductor structure of claim 4 wherein the linearization circuit comprises
an adaptive predistortion linearizer coupled in series with the power amplifier.

8. The semiconductor structure of claim 4 further comprising:
a controller responsive to an output signal to provide an adaptation signal to the adaptive predistortion linearizer.

9. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a power amplifier circuit;
an adaptive linearizer;
a coupler configured to sample an output signal; and
a control circuit coupled to the coupler and the adaptive linearizer, the control circuit configured to provide an adaptation signal to the adaptive linearizer in response to the sampled output signal.

10. The semiconductor structure of claim 9 wherein the power amplifier and the adaptive linearizer are formed in a compound semiconductor portion of the semiconductor structure and the controller is formed in a silicon portion of the semiconductor structure.

11. The semiconductor structure of claim 9 wherein the adaptive linearizer comprises:
means for distorting a signal in response to the adaptation signal.

12. The semiconductor structure of claim 11 wherein the control circuit comprises:
means for identifying a distortion in the sampled output signal;
means for determining a compensating predistortion; and
means for generating a signal as the adaptation signal to cause the means for distorting to compensatingly distort an input signal to the semiconductor structure and produce an output signal for amplification by the power amplifier circuit to form the output signal with reduced distortion.

13. The semiconductor structure of claim 12 wherein the power amplifier and the adaptive linearizer are formed in a compound semiconductor portion of the semiconductor structure and the controller is formed in a silicon portion of the semiconductor structure.

14. A semiconductor structure comprising:
a monocrystalline silicon substrate;
an amorphous oxide material overlying the monocrystalline silicon substrate;
a monocrystalline perovskite oxide material overlying the amorphous oxide material; and
a monocrystalline compound semiconductor material overlying the monocrystalline perovskite oxide material;
an input to receive a signal for power amplification;
two or more power amplifiers each operated in a linear mode;
a power splitting circuit coupled to the input and the two or more power amplifiers and configured to provide amplifier signals to each of the two or more power amplifiers, dividing signal power of the signal for power amplification among the two or more power amplifiers; and
a power combining circuit coupled to the two or more power amplifiers and configured to combine output signals from the two or more power amplifiers, producing an output signal.

15. The semiconductor structure of claim 14 wherein at least one power amplifier is formed at least in part on a silicon portion of the semiconductor structure and remaining power amplifiers are formed at least in part on a compound semiconductor portion of the semiconductor structure.

16. The semiconductor structure of claim 15 wherein the power splitting circuit and the power combining circuit are formed at least in part on the compound semiconductor portion of the semiconductor structure.

17. The semiconductor structure of claim 14 wherein the two or more power amplifiers are substantially identical.

18. The semiconductor structure of claim 14 further comprising an input amplifier coupled between the input and the power splitting circuit.

19. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
an input configured to receive a signal for power amplification;
an output configured to provide an amplified signal;
two or more power amplifiers each operated in a linear mode;
an input multiplexer coupled between the input and the two or more power amplifiers, the input multiplexer configured to separate the signal for power amplification into constituent signals and provide one or more constituent signals to respective power amplifiers; and
a combining circuit coupled between the two or more power amplifiers and the output and configured to combine amplifier output signals from the two or more power amplifiers and form the output signal.

20. The semiconductor structure of claim 19 wherein the combining circuit comprises an output multiplexer.

21. The semiconductor structure of claim 19 wherein the signal for power amplification comprises a plurality of carrier signals and wherein the input multiplexer is configured to separate the signal for power amplification into separate carrier signals, providing one carrier signal to each of the two or more power amplifiers.

22. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a feed forward amplifier configured to process an input signal to produce an output signal.

23. The semiconductor structure of claim 22 further comprising:
a splitter configured to receive the input signal;
an amplification circuit coupled with the splitter;
an error amplification circuit coupled with the splitter; and
a combiner coupled with the amplification circuit and the error amplification circuit to produce the output signal.

24. The semiconductor structure of claim 23 wherein the amplification circuit comprises:
an amplifier;
a coupler in series with the amplifier; and
a time delay circuit configured to provide an amplified, time delayed signal to the combiner.

25. The semiconductor structure of claim 24 wherein the error amplification circuit comprises:
a time delay circuit having a time delay substantially matching time delay of the amplifier;
a phase shifter coupled in series with the time delay circuit;
a coupler in series with the phase shifter and coupled with the amplification circuit coupler to produce an error signal; and
an error amplifier configured to provide an amplified, time delayed error signal to the combiner.

26. The semiconductor structure of claim 24 further comprising:
a control circuit configured to provide control signals to the amplification circuit and the error amplification circuit.

27. The semiconductor structure of claim 25 further comprising:
a coupler to sample the input signal and provide the sampled input signal to the control circuit; and
a coupler to sample the output signal and provide the sampled output signal to the control circuit.

28. The semiconductor structure of claim 26 wherein the control circuit is responsive to the sampled output signal and the sampled input signal to generate the control signals to minimize error between the sampled output signal and the sampled input signal.

29. The semiconductor structure of claim 26 wherein the amplification circuit comprises:
an amplifier;
a coupler in series with the amplifier; and
a time delay circuit.

30. The semiconductor structure of claim 29 wherein the error amplification circuit comprises:
a second time delay circuit having a time delay substantially matching time delay of the amplifier;
a phase shifter coupled in series with the time delay circuit;
a coupler in series with the phase shifter and coupled with the amplification circuit coupler to produce an error signal; and
an error amplifier to amplify the error signal.

31. The semiconductor structure of claim 30 wherein the control circuit is formed at least in part on a silicon portion of the semiconductor structure and the amplifier and the error amplifier are formed at least in part on a compound semiconductor portion of the semiconductor structure.

32. The semiconductor structure of claim 31 wherein the time delay circuit, the second time delay circuit and the phase shifter are formed at least in part on a compound semiconductor portion of the semiconductor structure.

33. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a power amplifier configured to amplify an input signal to produce an output signal; and
an error amplifier coupled with the power amplifier to produce a control signal for the power amplifier in response to the input signal and the output signal.

34. The semiconductor structure of claim 33 wherein the power amplifier has a gain control input to receive the control signal.

35. The semiconductor structure of claim 33 further comprising:
an input signal peak detector which provides an indication of peak values of the input signal to the error amplifier; and
an output signal peak detector which provides an indication of peak values of the output signal to the error amplifier.

36. The semiconductor structure of claim 33 further comprising:
an input coupler to sample the input signal for provision to the error amplifier;
an output coupler to sample the output signal;
an attenuator coupled with the output coupler to attenuate the output signal for provision to the error amplifier.

37. The semiconductor structure of claim 36 further comprising:
an input signal peak detector which provides an indication of peak values of the sampled input signal to the error amplifier; and
an output signal peak detector which provides an indication of peak values of the sampled output signal to the error amplifier.

38. The semiconductor structure of claim 33 wherein the power amplifier is formed at least in part on a compound semiconductor portion of the semiconductor structure and the error amplifier is formed at least in part on a silicon portion of the semiconductor structure.

39. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming at least in part in the monocrystalline compound semiconductor layer a power amplifier; and
forming at least in part in a silicon portion of the semiconductor structure a linearization circuit for the power amplifier.

40. The process of claim 39 further comprising:
forming an epitaxial silicon layer,
the silicon portion including at least one of the monocrystalline silicon substrate and the epitaxial silicon layer.

41. The process of claim 39 wherein forming the linearization circuit for the power amplifier comprises forming a circuit defining predistortion linearizer coupled in series with the power amplifier.

42. The process of claim 39 wherein forming the linearization circuit for the power amplifier comprises forming a first circuit defining an adaptive linearizer coupled in series with the power amplifier and a second circuit defining a control circuit coupled with the power amplifier and the adaptive linearizer.

43. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming at least in part in the monocrystalline compound semiconductor layer two or more power amplifiers;
forming power splitting circuit between an input and the two or more power amplifiers; and
forming a power combining circuit between the two or more power amplifiers and an output.

44. The process of claim 44 wherein forming the power splitting circuit comprises forming devices defining the power splitting circuit at least in part in the monocrystalline compound semiconductor layer of the semiconductor structure.

45. The process of claim 44 wherein forming the power combining circuit comprises forming devices defining the power combining circuit at least in part in the monocrystalline compound semiconductor layer of the semiconductor structure.

46. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming at least in part in the monocrystalline compound semiconductor layer two or more power amplifiers;
forming an input multiplexer coupled between the input and the two or more power amplifiers; and
forming a combining circuit coupled between the two or more power amplifiers and an output.

47. The process of claim 46 wherein forming the input multiplexer comprises forming devices to define the input multiplexer at least in part in a silicon portion of the semiconductor structure.

48. The process of claim 44 wherein forming the combining circuit comprises forming devices defining the power combining circuit at least in part in the monocrystalline compound semiconductor layer of the semiconductor structure.

49. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming a feed forward amplifier at least in part in the monocrystalline compound semiconductor layer.

50. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming a power amplifier configured to amplify an input signal to produce an output signal; and
forming an error amplifier coupled with the power amplifier to produce a control signal for the power amplifier in response to the input signal and the output signal.

51. The process of claim 50 wherein forming the power amplifier comprises forming devices at least in pat in the monocrystalline compound semiconductor layer to define the power amplifier.
